(19) United States
(12) Patent Application Publication
(10) Pub. No.: US 2004/0090279 A1
(43) Pub. Date: May 13, 2004

(54) Semiconductor device

(75) Inventor: Hiroshi Seki, Suwa-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 10/647,224

(22) Filed: Aug. 26, 2003

(30) Foreign Application Priority Data
Sep. 11, 2002 (JP) 2002-265284

(51) Int. Cl. H03B 5/32

(52) U.S. Cl. 331/158

(57) ABSTRACT

The invention provides a semiconductor device by which the size of an inverting amplifier being capable of intermittently outputting an oscillation signal can be downsized. The semiconductor device can be installed in parallel with an oscillator and include an inverting amplifier intermittently outputting oscillation signal in response to control signal. The inverting amplifier can include a transmission gate set to an “on” state where a first signal is transmitted in a case of the control signal being set to an H level, and set to an “off” state where a first signal is not transmitted in a case of the control signal being set to an L level, an inverter inverting a logical level of a signal given so as to output a second signal, and a clamping circuit set to make the first signal applied to an input terminal of the inverter in a case of the control signal being set to the level, and set to make predetermined voltage applied to the input terminal of the inverter when the control signal is set to a second logical level.

### BACKGROUND OF THE INVENTION

1. Field of Invention

The present invention relates to an art of an oscillation circuit including a semiconductor device.

2. Description of Related Art

A large number of MOS transistors have been used for a semiconductor device, such as an integrated circuit. A circuit in a semiconductor device operates in response to a given clock signal. Thus, a crystal oscillator is usually installed outside a semiconductor device, and an oscillation circuit including a crystal oscillator is formed outside and inside of a semiconductor device.

FIG. 1 is an explanatory diagram showing a basic constitution of a conventional oscillation circuit 900. As shown in the diagram, the oscillation circuit 900 can include a crystal oscillator 910, a feedback resistor 920 connected in parallel to the crystal oscillator, an inverting amplifier 960 connected in parallel to the crystal oscillator, and a buffer 970 connected to an output terminal of the inverting amplifier. Here, in FIG. 1, the crystal oscillator 910 and the feedback resistor 920 are installed outside a semiconductor device 950. In addition, the inverting amplifier 960 and the buffer 970 are installed inside the semiconductor device 950 and formed by using the MOS transistors.

In FIG. 1, the inverting amplifier 960 can include a two-inputs NAND circuit. A signal S1 is applied to one input terminal from the crystal oscillator 910, and a control signal CTR is applied to the other input terminal. When the control signal CTR is set to an H level, the inverting amplifier 960 outputs an oscillation signal S2. On the other hand, the control signal CTR is set to an L level, the inverting amplifier 960 invariably outputs a signal S2, which is at the H level. Hence, the inverting amplifier 960 can intermittently output an oscillation signal in response to the given control signal CTR. Here, the conventional oscillation circuits include, for example, the type disclosed in Japanese Unexamined Patent Application Publication No. 11-289243.

### SUMMARY OF THE INVENTION

However, when the inverting amplifier 960 being capable of intermittently outputting the oscillation signal is formed by using the two-inputs NAND circuit, the size of the inverting amplifier becomes large. Namely, the two-inputs NAND circuit needs a relatively large area inside the semiconductor device 950. The reason is that, in the two-inputs NAND circuit, two n-channel type MOS transistors are connected each other in series between internal power source voltage and an output signal line of the semiconductor device 950.

In order to solve the above problems in a conventional art, the present invention is intended to provide an art of downsizing an inverting amplifier being capable of intermittently outputting the oscillation signal.

In order to solve at least a part of the above problems, a first device of the present invention is a semiconductor device utilizing an oscillator installed outside and comprising an inverting amplifier, which is installed in parallel with the oscillator, for intermittently outputting an oscillation signal in response to a given control signal. The inverting amplifier can include a first terminal for receiving a first signal from the oscillator, a second terminal for providing a second signal to the oscillator, a transmission gate installed between the first terminal and the second terminal, formed by using insulated gate transistors, set to an ‘on’ state where the first signal is transmitted in a case of the control signal being set to a first logical level, and set to an ‘off’ state where the first signal is not transmitted in the other case of the control signal being set to a second logical level, an inverter installed between an output terminal of the transmission gate and the second terminal, formed by using the insulated gate transistors, and inverting a logical level of a given signal so as to output the second signal, and a clamping circuit installed between the output terminal of the transmission gate and an input terminal of the inverter, formed by using the insulated gate transistor, set to make the first signal output from the transmission gate applied to the input terminal of the inverter in a case of the control signal being set to the first logical level, and set to make predetermined voltage applied to the input terminal of the inverter in the other case of the control signal being set to the second logical level.

In the device, because the inverting amplifier can be formed by using the transmission gate, the inverter, and the clamping circuit, it is unnecessary that two insulated gate transistors are connected each other in series between the internal power source voltage and the output signal line. Therefore, the size of the inverting amplifier being capable of intermittently outputting the oscillation signal can be downsized. Here, in the present specification, in the situation where the clamping circuit is installed between the output terminal of the transmission gate and the input terminal of the inverter includes the case where one terminal of the clamping circuit is connected to the output terminal of the transmission gate and the input terminal of the inverter.

the device, it is preferable that the transmission gate is a CMOS transmission gate, a combination of n-channel type MOS transistors and p-channel type MOS transistors. The above structure provides superior transmission property. Here, instead of this, the transmission gate including only the n-channel type MOS transistors or the transmission gate including only the p-channel type MOS transistors may be used. Furthermore, in the device, can include a buffer, which is formed by using the insulated gate transistors, for transmitting the signal output from the inverting amplifier to other circuits. Furthermore, in the device, it is preferable that a transmission gate be installed between the inverting amplifier and the buffer and formed by using the insulated gate transistors.

The above structure can restrict damage of a gate insulating film of a transistor due to static electricity. In particular, because a first transmission gate is installed in the inverting amplifier, utilizing an “on” resistance of the first transmission gate can restrict damage of a gate insulating film of a transistor included in the inverter due to static electricity. In addition, because a second transmission gate is installed between the inverting amplifier and the buffer, utilizing an “on” resistance of the second transmission gate can restrict damage of a gate insulating film of a transistor included in the buffer due to static electricity.

In the device, it is preferable that the semiconductor device utilizing an oscillator further include a feedback resistor installed in parallel with the oscillator. Thus, utilizing the feedback resistor can make the oscillator certainly oscillated. Here, the feedback resistor may be installed outside the semiconductor device, or inside the semiconductor device.

A second device of the present invention is an oscillation circuit can include an oscillator, and a semiconductor device utilizing the oscillator. The semiconductor device can include an inverting amplifier, which is installed in parallel with the oscillator, for intermittently outputting an oscillation signal in response to a given control signal. The inverting amplifier can include a first terminal for receiving a first signal from the oscillator, a second terminal for providing a second signal to the oscillator, a transmission gate installed between the first terminal and the second terminal, formed by using insulated gate transistors, set to an ‘on’ state where the first signal is transmitted in a case of the control signal being set to a first logical level, and set to an ‘off’ state where the first signal is not transmitted in the other case of the control signal being set to a second logical level, an inverter installed between an output terminal of the transmission gate and the second terminal, formed by using the insulated gate transistors, and inverting a logical level of a given signal so as to output the second signal, and a clamping circuit installed between the output terminal of the transmission gate and an input terminal of the inverter, formed by using the insulated gate transistor, set to make the first signal output from the transmission gate applied to the input terminal of the inverter in a case of the control signal being set to the first logical level, and set to make predetermined voltage applied to the input terminal of the inverter in the other case of the control signal being set to the second logical level.

The above device has the same constitution of the first device so as to have the same functions and effects of the first device, enabling the inverting amplifier, which can intermittently output the oscillation signal, to be downsized.

Here, the present invention can be applied to various aspect of a semiconductor device, an oscillation circuit including a semiconductor device, and electric equipment including an oscillation circuit.

### BRIEF DESCRIPTION OF THE DRAWINGS

The invention will be described with reference to the accompanying drawings, wherein like numerals reference like elements, and wherein:

FIG. 1 is an explanatory diagram showing a basic constitution of a conventional oscillation circuit 900;

FIG. 2 is an explanatory diagram showing an oscillation circuit 100 of a first example;

FIG. 3 is an explanatory diagram showing a schematic constitution of an inverting amplifier 160 in FIG. 2;

FIG. 4 is an explanatory diagram showing a schematic constitution of a conventional inverting amplifier 960 in FIG. 1;

FIG. 5 is an explanatory diagram showing a concrete constitution of the conventional inverting amplifier 960 in FIG. 1;

FIG. 6 is an explanatory diagram showing a concrete constitution of the conventional inverting amplifier 160 in FIG. 2 and corresponds to FIG. 3;

FIG. 7 is an explanatory diagram showing a first inverting amplifier 160A of a second example;

FIG. 8 is an explanatory diagram showing a second inverting amplifier 160B of the second example;

FIG. 9 is an explanatory diagram showing an inverting amplifier 160C of a third example;

FIG. 10 is an explanatory diagram showing an inverting amplifier 160D of a fourth example; and

FIG. 11 is an explanatory diagram showing an oscillation circuit 100E of a fifth example.

### DETAILED DESCRIPTION OF PREFERRED EMBODIMENTS

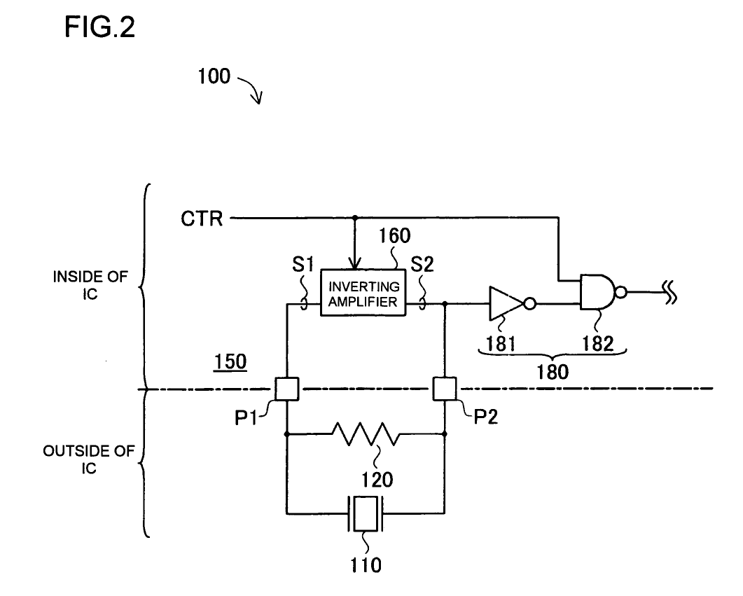

An embodiment of the present invention will be described based on examples. FIG. 2 is an explanatory diagram showing an oscillation circuit 100 of a first example. Here, as shown in the diagram, the oscillation circuit 100 can be formed by using a semiconductor device 150. The oscillation circuit 100 can include a crystal oscillator 110, a feedback resistor 120 connected in parallel to the crystal oscillator, and an inverting amplifier 160 connected in parallel to the crystal oscillator. Here, the oscillation circuit 100 can also include a buffer 180 connected to the output terminal of the inverting amplifier 160.

In FIG. 2, the crystal oscillator 110 and the feedback resistor 120 can be installed outside the semiconductor device 150, and the inverting amplifier 160 and the buffer 180 are installed inside the semiconductor device 150. Here, the inside and outside of the semiconductor device 150 are electrically connected each other via a plurality of pins installed in the semiconductor device 150. As for the oscillation circuit 100 in FIG. 2, a circuit part installed outside the semiconductor device 150 and the circuit part installed inside the semiconductor device 150 are electrically coupled to each other via two pins P1 and P2, to which the crystal oscillator 110 is connected.

Meanwhile, in the present example, a gate array is used as the semiconductor device 150. Here, the gate array is a device, which is classified as a custom IC among application specific integrated circuits (ASIC). The semiconductor device 150 can include an internal cell area where basic cells are arranged in a matrix. Here, the basic cells include p-channel type MOS transistors (referred to as pMOS transistor hereafter) and n-channel type MOS transistors (referred to as nMOS transistor hereafter).

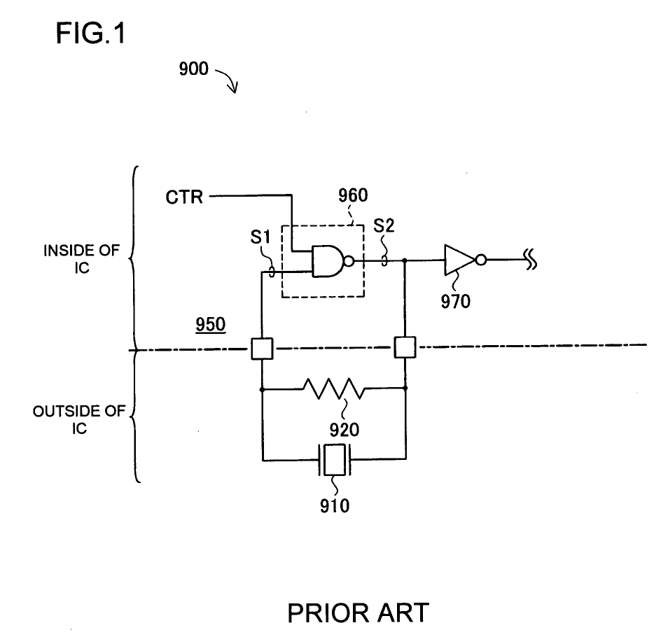

The control signal CTR is applied to the inverting amplifier 160. The inverting amplifier 160 outputs a signal, which is the same output from the conventional inverting amplifier 960 including only two-inputs NAND circuit shown in FIG. 1. The signal is output in response to the control signal CTR. In particular, when the control signal CTR is set to an H level, the crystal oscillator 110 oscillates, hereat the inverting amplifier 160 outputs the oscillation signal S2 produced by inverting a logical level of the feedback signal S1 applied from the crystal oscillator 110. On the other hand, when the control signal CTR is set to an L level, oscillation of the crystal oscillator 110 stops, hereat the signal S1, which is at the L level, is invariably applied to the inverting amplifier 160 such that the inverting amplifier 160 invariably outputs the signal S2, which is at the H level. Here, details of the inverting amplifier 160 will be further described in greater detail below.

The buffer 180 can include an inverter 181 and a two-inputs NAND circuit 182. The buffer 180 functions to rectify a waveform of the oscillation signal S2 applied from the inverting amplifier 160 and provide a clock signal to other circuit (for example, a frequency divider) inside the semiconductor device 150. The control signal CTR is applied to the two-inputs NAND circuit 182 included in the buffer 180. When the control signal CTR is set to the H level, the two-inputs NAND circuit 182 outputs the signal (namely, the clock signal) produced by inverting the logical level of the signal (namely, the oscillation signal S2, of which the logical level is inverted by the inverter 181) applied from the inverter 181. On the other hand, when the control signal CTR is set to the L level, the two-inputs NAND circuit 182 invariably outputs the signal, which is at the H level.

According to this constitution, the oscillation circuit 100 can intermittently output the clock signal in response to the control signal CTR. In particular, the oscillation circuit 100 can output the clock signal when the control signal CTR is set to the H level, and can stop outputting the clock signal when the control signal CTR is set to the L level.

As the above, in the present example, the control signal CTR can be applied to the inverting amplifier 160 and the two-inputs NAND circuit 182. Providing the control signal CTR to the inverting amplifier 160 can stop the oscillation of the crystal oscillator 110 when the control signal is set to the L level such that current consumption at the inverting amplifier 160 can be reduced. Further, providing the control signal CTR to the two-inputs NAND circuit 182 can rapidly stop outputting the clock signal when the control signal is set to the L level. Here, the control signal CTR may be applied to only the inverting amplifier 160. In this case, the oscillation circuit 100 can intermittently output the clock signal in response to the control signal CTR, too.

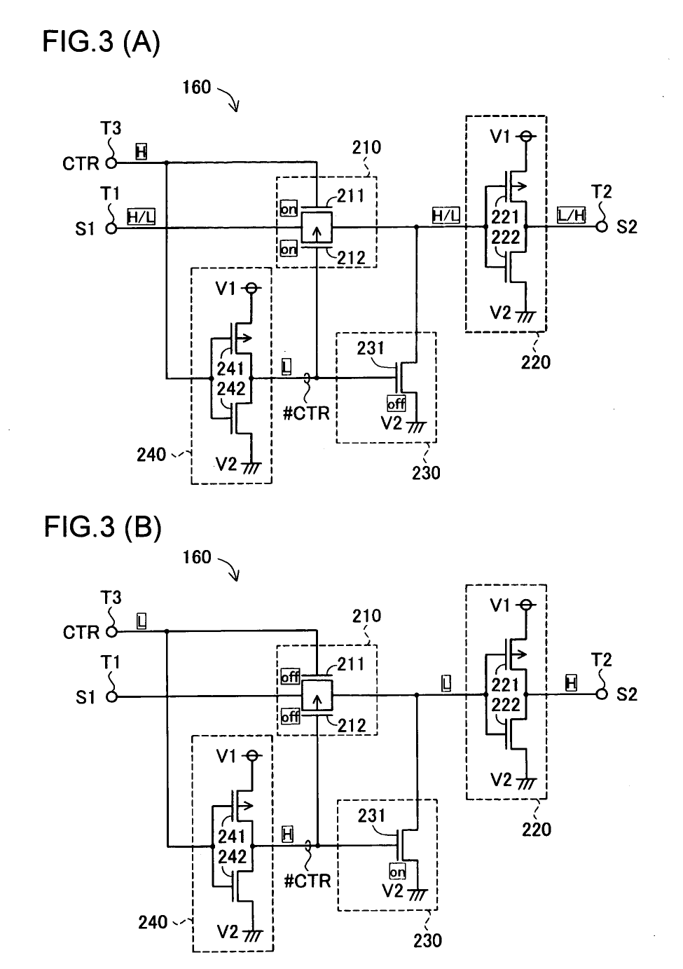

FIG. 3 is an explanatory diagram showing a schematic constitution of the inverting amplifier 160 in FIG. 2. Here, in FIG. 3(A), operation at the time when the control signal CTR applied to the inverting amplifier 160 is at the H level is shown. In FIG. 3(B), operation at the time when the control signal CTR applied to the inverting amplifier 160 is at the L level is shown.

As shown in the diagram, the inverting amplifier 160 can include a first terminal (input terminal) T1 for receiving the first signal S1 from the crystal oscillator 110, a second terminal (output terminal) T2 for providing the second signal S2 to the crystal oscillator 110 and the buffer 180, and a third terminal (control terminal) T3 for receiving the control signal CTR. In addition, the inverting amplifier 160 can include a transmission gate 210, a first inverter 220, a clamping circuit 230, and a second inverter 240. Here, the transmission gate is also referred to as a transfer gate or a path transistor.

The transmission gate 210 and the first inverter 220 are installed between the first terminal T1 and the second terminal T2 in that order. In particular, the first terminal T1 of the inverting amplifier 160 is connected to the input terminal of the transmission gate 210. The output terminal of the transmission gate 210 is connected to the input terminal of the inverter 220. The output terminal of the first inverter 220 is connected to the second terminal T2 of the inverting amplifier 160. Further, the clamping circuit 230 is installed between the transmission gate 210 and the first inverter 220.

The transmission gate 210 is a CMOS transmission gate, a combination of an nMOS transistor 211 and a pMOS transistor 212. A drain of the nMOS transistor 211 and the drain of the pMOS transistor 212 are connected each other to function as the input terminal. In addition, a source of the nMOS transistor 211 and the source of the pMOS transistor 212 are connected each other to function as the output terminal. The control signal CTR is applied to a gate of the nMOS transistor 211, and a control signal #CTR produced by inverting the logical level is applied to the gate of the pMOS transistor 212.

The first inverter 220 is a CMOS inverter and can include a pMOS transistor 221 and an nMOS transistor 222, which are connected each other in series. The gate of the pMOS transistor 221 and the gate of the nMOS transistor 222 are connected each other to function as the input terminal. In addition, the drain of the pMOS transistor 221 and the drain of the nMOS transistor 222 are connected each other to function as the output terminal. Further, the source of the pMOS transistor 221 is set to the first internal power source voltage V1 of the semiconductor device 150, and the source of the nMOS transistor 222 is set to the second internal power source voltage V2 (ground potential in the present example) of the semiconductor device 150.

The clamping circuit 230 can include an nMOS transistor 231. The source of the nMOS transistor 231 is set to the second internal power source voltage V2 (ground potential in the present example) of the semiconductor device 150, and the drain of it is connected to the output terminal of the transmission gate 210 and the input terminal of the first inverter 220. In addition, the control signal #CTR produced by inverting the logical level is applied to the gate of the nMOS transistor 231.

The second inverter 240 is the same CMOS inverter as the first inverter 220 and includes a pMOS transistor 241 and an nMOS transistor 242, which are connected each other in series. The control signal CTR is applied to the input terminal of the second inverter 240. Further, the output terminal of the second inverter 240 is connected to the gate of the pMOS transistor 212 included in the transmission gate 210 and the gate of the nMOS transistor 231 included in the clamping circuit 230.

As shown in FIG. 3(A), when the control signal CTR is at the H level, both the nMOS transistor 211 and the pMOS transistor 212, which constitute the transmission gate 210, are set to an “on” state. Hereat, voltage applied to the input terminal of the transmission gate 210 is output from the output terminal as the voltage value is almost equal. Further, when the control signal CTR is at the H level, the nMOS transistor 231 constituting the clamping circuit 230 is set to an “off” state. Therefore, an output from the transmission gate 210 is applied to the input terminal of the first inverter 220 as it is. Further, the first inverter 220 outputs the signal produced by inverting the logical level of the given signal. In particular, when an input is at the H level, only the nMOS transistor 222 is set to the “on” state such that the first inverter 220 outputs the signal at the L level. In addition, when the input is at the L level, only the pMOS transistor 221 is set to the “on” state such that the first inverter 220 outputs the signal at the H level.

On the other hand, as shown in FIG. 3(B), when the control signal CTR is at the L level, both the nMOS transistor 211 and the pMOS transistor 212, which constitute the transmission gate 210, are set to the “off” state. Hereat, the output of the transmission gate 210 is set to be in a state of high impedance. Further, when the control signal CTR is at the L level, the nMOS transistor 231 constituting the clamping circuit 230 is set to the “on” state. Therefore, the input terminal of the first inverter 220 is set to the L level such that the first inverter 220 invariably outputs the signal at the H level.

As the above, when the control signal CTR is at the H level, the inverting amplifier 160 can output the oscillation signal S2 produced by inverting the logical level of the signal S1 applied to the first terminal T1, from the second terminal T2. In addition, when the control signal CTR is at the L level, the inverting amplifier 160 can invariably output the signal S2, which is at the H level, from the second terminal T2.

Incidentally, as the above, the inverting amplifier 160 of the present example outputs the same signal from the conventional inverting amplifier 960, which is shown in FIG. 1, including only the two-inputs NAND circuit in response to the given control signal CTR. However, as shown in FIG. 3, the two-inputs NAND circuit is not used in the inverting amplifier 160 of the present example. Consequently, the size of the inverting amplifier 160 can be considerably downsized inside the semiconductor device (gate array) 150. Here, the two-inputs NAND circuit includes two nMOS transistors connected each other in series between the internal power source voltage and the output signal line such that the size of the inverting amplifier 960 having the two-inputs NAND circuit becomes large.

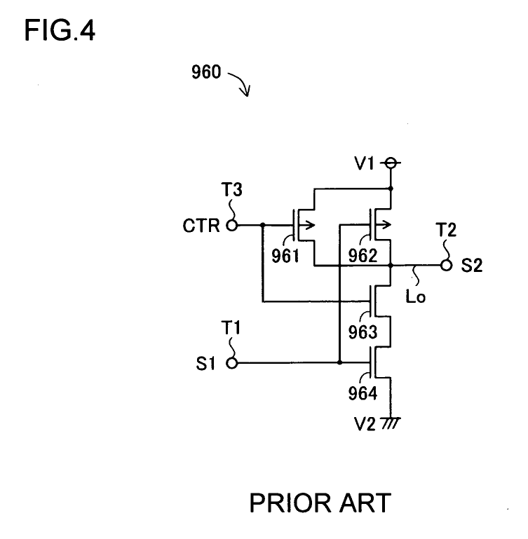

FIG. 4 is an explanatory diagram showing a schematic constitution of an exemplary conventional inverting amplifier 960 in FIG. 1. As shown in the diagram, the two-inputs NAND circuit can include two pMOS transistors 961 and 962, and two nMOS transistors 963 and 964. The first and second pMOS transistors 961 and 962 are connected each other in parallel between the first internal power source circuit V1 and an output signal line Lo connecting to the second terminal T2. In addition, the first and second nMOS transistors 963 and 964 are connected each other in series between the output signal line Lo and the second internal power source voltage V2.

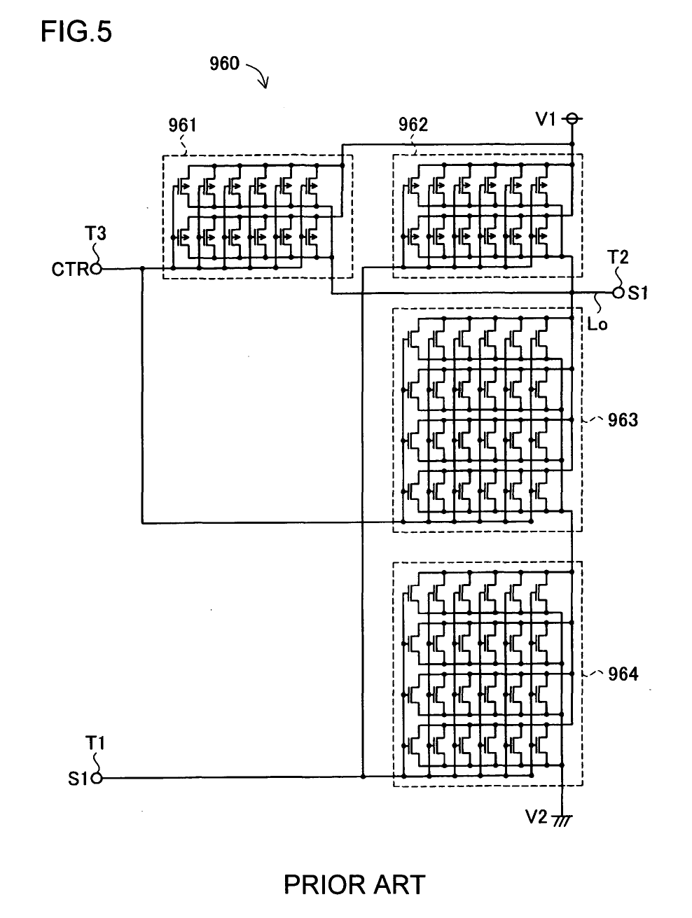

FIG. 5 is an explanatory diagram showing an exemplary conventional inverting amplifier 960 in FIG. 1, and corresponds to FIG. 4. As shown in the diagram, each of two pMOS transistors 961 and 962 include twelve pMOS transistor components connected each other in parallel. In addition, each of two nMOS transistors 963 and 964 includes twenty-four nMOS transistor components connected each other in parallel. As can be seen from FIG. 5, the conventional inverting amplifier 960 comprises a total of seventy-two transistor components.

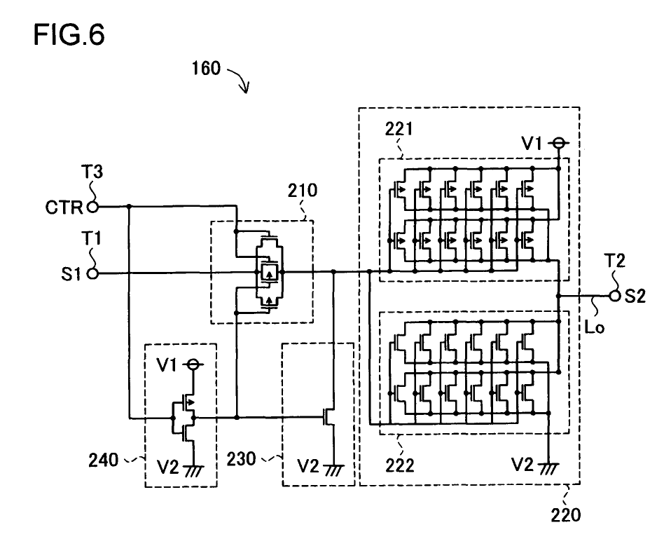

FIG. 6 is an explanatory diagram showing a concrete constitution of the inverting amplifier 160 in FIG. 2, and corresponds to FIG. 3. As shown in the diagram, the transmission gate 210 can include two nMOS transistor components connected each other in parallel and two pMOS transistor components connected each other in parallel in the inverting amplifier 160 of the present example. In addition, the pMOS transistor 221 included in the inverter 220 includes twelve pMOS transistor components connected each other in parallel, and the nMOS transistor 222 comprises twelve nMOS transistor components connected each other in parallel. Furthermore, the clamping circuit 230 includes one nMOS transistor component, and the second inverter 240 includes one pMOS transistor component and one nMOS transistor component. As can be seen from FIG. 6, the inverting amplifier 160 of the present example have a total of thirty-one transistor components.

Incidentally, the two-inputs NAND circuit in FIG. 5 and the first inverter 220 in FIG. 6 can include a large number of transistor components so as to operate the inverting amplifier with relatively high frequency (for example, about 80 MHz through about 100 MHz). Namely, the inverting amplifier needs to drive relatively large current because of its operation with relatively high frequency such that the inverting amplifier needs to have relatively small resistance value.

The inverting amplifier 160 of the present example shown in FIG. 6 has the same current driving ability of the conventional inverting amplifier 960 shown in FIG. 5. However, as can be expected from comparison between FIG. 5 and FIG. 6, the inverting amplifier 160 in FIG. 6 can have a relatively small amount of transistor components. The reason is that the inverting amplifier 960 in FIG. 5 has the two-inputs NAND circuit, and the two-inputs NAND circuit include two nMOS transistors 963 and 964, which are connected each other in series between the output signal line Lo and the second internal power source voltage V2.

In particular, in the inverting amplifier 160 in FIG. 6, if the “on” resistance of the pMOS transistor 221 and the nMOS transistor 222 in the first inverter 220 are respectively presumed to be R, it is necessary that the “on” resistance of each pMOS transistor 961 and 962 included in the two-inputs NAND circuit is R, and the combined “on” resistance of two nMOS transistors 963 and 964 connected each other in series is R so that the inverting amplifier 960 in FIG. 5 has the same current driving ability of the inverting amplifier 160 in FIG. 6. Therefore, the “on” resistance of each nMOS transistors 963 and 964 needs to be set to R/2.

The “on” resistance of the transistor component is in proportion to L/W. Here, L means a gate length (equal to a channel length), and W means a gate width. If the gate width W of the transistor component is set to double, the “on” resistance of the transistor component can be set to half. In addition, when the size of each transistor component is identical to each other, if the transistor components of double number are connected each other in parallel, the gate width W of transistor component group can be practically set to double such that the “on” resistance of transistor component group can be set to half.

In FIG. 5 and FIG. 6, the size of each transistor component is set to be identical. Hence, each of nMOS transistors 963 and 964 included in the two-inputs NAND circuit is constituted by connecting the transistor components, of which number is twice (namely, twenty-four) of the number of transistor components constituting the nMOS transistor 222 included in the first inverter 220 (namely, twelve), each other in parallel. As a result, the conventional inverting amplifier 960 needs a relatively large number of the transistor components (seventy-two). On the other hand, in the present example, the inverting amplifier 160 does not include two nMOS transistors connected each other in series such that the inverting amplifier 160 can include a relatively small number of the transistor components (thirty-one).

Here, though the inverting amplifier 160 includes the second inverter 240 for inverting the logical level of the control signal CTR in the present example, the inverter 240 can be omitted. In this case, the inverting amplifier has only to comprise a fourth terminal for receiving the control signal #CTR produced by inverting the logical level, as well as the third terminal T3 for receiving the control signal CTR.

As described in the above, the oscillation circuit 100 of the present example can include the crystal oscillator 110 and the semiconductor device 150 utilizing the crystal oscillator. The semiconductor device 150 is installed in parallel with the crystal oscillator and includes the inverting amplifier 160 for intermittently outputting the oscillation signal in response to the given control signal CTR. Further, the inverting amplifier can have the transmission gate 210 installed between the first terminal T1 and the second terminal T2, the first inverter 220 installed between the output terminal of the transmission gate and the second terminal T2, and the clamping circuit 230 installed between the output terminal of the transmission gate 210 and the input terminal of the first inverter 220. Here, the transmission gate 210 is set to be the “on” state where the first signal S1 is transmitted when the control signal CTR is set to the H level, and is set to be the “off” state where the first signal S1 is not transmitted when the control signal CTR is set to the L level. The first inverter 220 inverts the logical level of the given signal so as to output the second signal S2. The clamping circuit 230 is set to make the first signal S1 output from the transmission gate applied to the input terminal of the first inverter 220 in a case of the control signal CTR being set to the H level, and is set to make the almost same voltage as the second internal power source voltage V2 (namely, L level) applied to the input terminal of the first inverter 220 in a case of the control signal CTR being set to the L level.

As described, in the oscillation circuit 100 of the present example, because the inverting amplifier 160 can be formed by using the transmission gate 210, the first inverter 220, and the clamping circuit 230, it is unnecessary that nMOS transistors are connected each other in series between the second internal power source voltage V2 and the output signal line Lo. Therefore, the size of the inverting amplifier 160 being capable of intermittently outputting the oscillation signal can be downsized.

Here, though the inverting amplifier 160 includes the transmission gate 210 in the present example, the transmission gate 210 can be omitted when the inverting amplifier comprises the clamping circuit 230. In this constitution, when the control signal CTR is set to the L level, the inverting amplifier can stop outputting the oscillation signal, too, by applying relative large current to the clamping circuit 230. However, the constitution of the present example can set a state of high impedance at the transmission gate 210 when the control signal CTR is set to the L level, enabling a current passing through the clamping circuit 230 to be small. As a result, the current consumption at the time of stopping the oscillation signal can be reduced. Hence, the inverting amplifier 160 of the present example comprises the transmission gate 210.

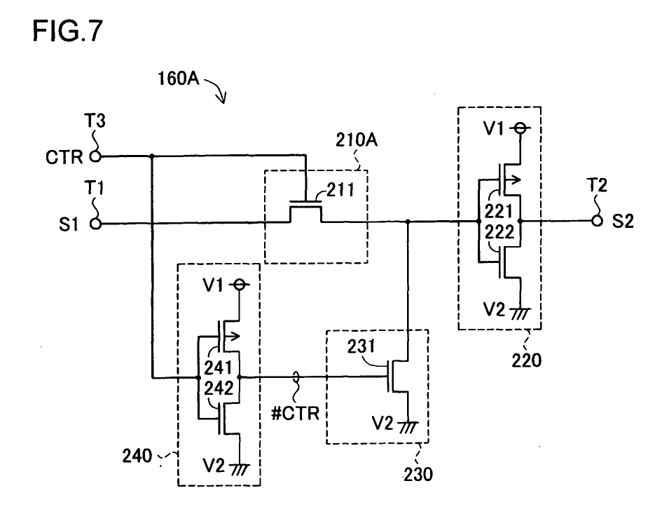

FIG. 7 is an explanatory diagram showing a first inverting amplifier 160A of a second example. The inverting amplifier 160A is almost same as the inverting amplifier 160 of the first example (FIG. 3) except that it includes a transmission gate 210A having only the nMOS transistor 211.

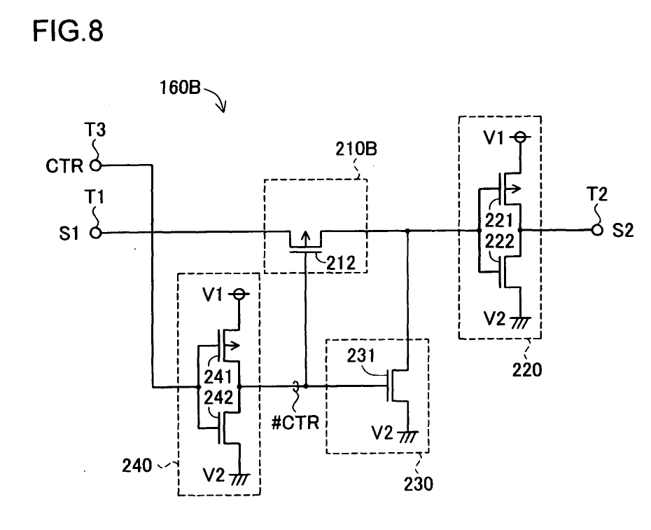

FIG. 8 is an explanatory diagram showing a second inverting amplifier 160B of a second example. The inverting amplifier 160B is almost same as the inverting amplifier 160 of the first example (FIG. 3), too, except that it includes a transmission gate 210B having only the pMOS transistor 212.

In the constitution of the present example (FIG. 7, FIG. 8), as well as the constitution of the first example (FIG. 3), the inverting amplifiers 160A and 160B output the oscillation signal S2 produced by inverting the logical level of the signal S1 applied to the first terminal T1, from the second terminal T2 when the control signal CTR is set to the H level. In addition, the inverting amplifiers 160A and 160B invariably output the signal S2, which is at the H level, from the second terminal T2.

However, though the transmission gate 210A shown in FIG. 7 is superior in transmission property for the inputs at the L level, it is inferior in transmission property for the inputs at the H level. The reason is that output voltage from the nMOS transistor 211 is limited to voltage value, which is equal to gate voltage minus threshold voltage, or less. On the contrary, though the transmission gate 210B shown in FIG. 8 is superior in transmission property for the inputs at the H level, it is inferior in transmission property for the inputs at the L level. The reason is that output voltage from the pMOS transistor 212 is limited to voltage value, which is equal to gate voltage plus threshold voltage, or more. On the other hand, the transmission gate 210 shown in FIG. 3 can utilize advantages of two transistors 211 and 212 such that it is superior in the transmission property for inputs at both the H level and the L level. Namely, the transmission gate 210 in FIG. 3 has an advantage that good transmission property can be obtained.

As can be expected from explanations of the first example and the second example, generally, it is sufficient that the transmission gate is set to the “on” state where the first signal is transmitted when the control signal is set to a first logical level, and is set to the “off” state where the first signal is not transmitted when the control signal is set to a second logical level.

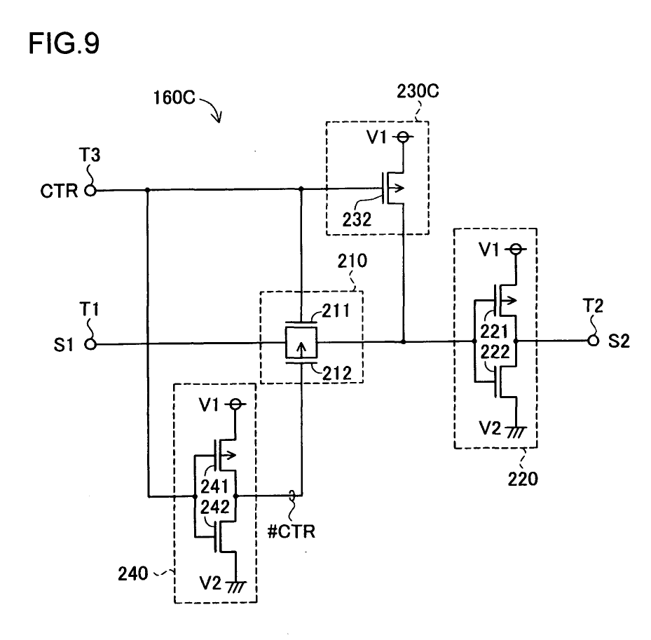

FIG. 9 is an explanatory diagram showing an inverting amplifier 160C of a third example. The inverting amplifier 160C is the almost same as the inverting amplifier 160 of the first example (FIG. 3) except that the clamping circuit is changed to a clamping circuit 230C.

In particular, the clamping circuit 230C of the present example can include a pMOS transistor 232. The source of the pMOS transistor is set to the first internal power source voltage V1 of the semiconductor device 150, and the drain of it is connected to the input terminal of the transmission gate 210 and the input terminal of the first inverter 220. In addition, the control signal CTR is applied to the gate of the pMOS transistor.

In the present example, when the control signal CTR is set to the H level, the inverting amplifier 160C outputs the oscillation signal S2 produced by inverting the logical level of the signal S1 applied to the first terminal T1. In addition, when the control signal CTR is set to the L level, the inverting amplifier 160C invariably outputs the signal S2, which is at the L level, from the second terminal T2. In particular, when the control signal CTR is set to the L level, the pMOS transistor 232 constituting the clamping circuit 230 is set to the “on” state. Hereat, the input terminal of the first inverter 220 is set to the H level such that the first inverter 220 invariably outputs the signal at the L level.

can be expected from explanations of the first and third examples, it is generally sufficient that the clamping circuit is set to make the first signal output from the transmission gate applied to the input terminal of the inverter in a case of the control signal being set to the first logical level, and is set to make predetermined voltage applied to the input terminal of the inverter in a case of the control signal being set to the second logical level.

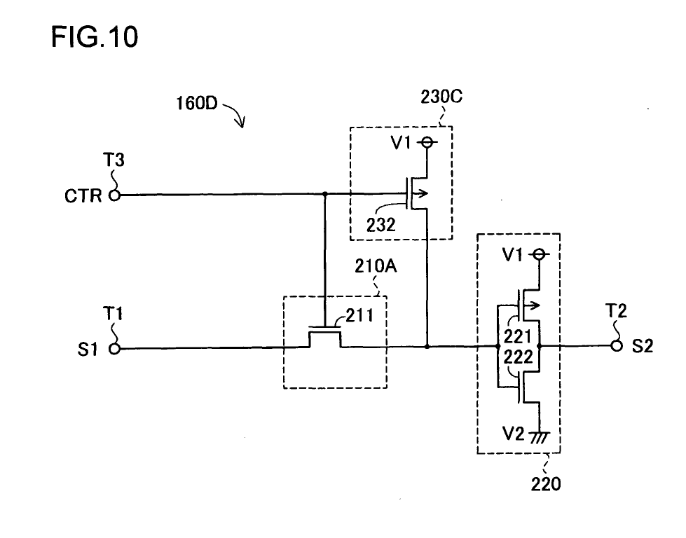

FIG. 10 is an explanatory diagram showing an inverting amplifier 160D of a fourth example. The inverting amplifier 160D is equivalent to a combination of the constitution of the second example (FIG. 7) and it of the third example (FIG. 9).

In particular, the inverting amplifier 160D can include the transmission gate 210A having only the nMOS transistor 211, the first inverter 220, and the clamping circuit 230C having the pMOS transistor 232. In the constitution of the present example, it is unnecessary that the control signal #CTR produced by inverting the logical level is produced. Hence, the second inverter 240 in FIG. 3 can be omitted such that the size of the inverting amplifier can be further downsized.

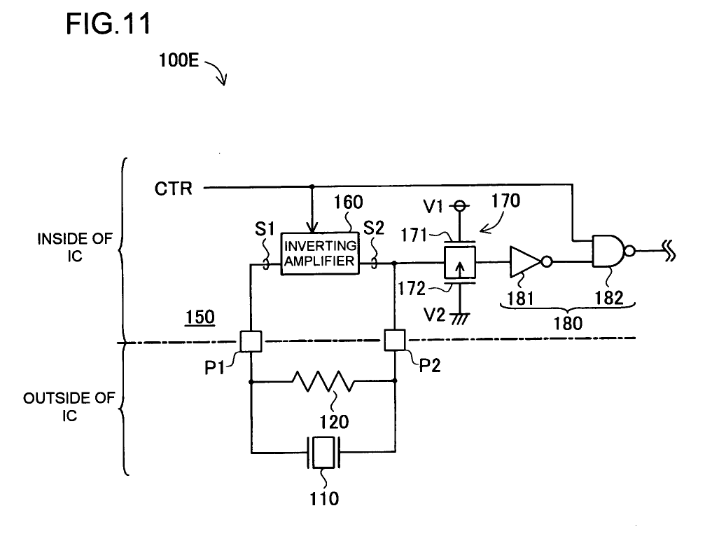

FIG. 11 is an explanatory diagram showing an oscillation circuit 100E of a fifth example. The oscillation circuit 100E is almost same as the oscillation circuit 100 of the first example (FIG. 2) except that a transmission gate 170 is added to between the inverting amplifier 160 and the buffer 180.

As with the transmission gate 210 (FIG. 3) included in the inverting amplifier 160, the transmission gate 170 is the CMOS transmission gate, a combination of an nMOS transistor 171 and a pMOS transistor 172. Here, the gate of the nMOS transistor 171 is set to the first internal power source voltage V1 of the semiconductor device 150 and the gate of the pMOS transistor 172 is set to the second internal power source voltage V2 (a ground potential in this example) of it. Hence, the transmission gate 170 is always set to the “on” state.

According to the constitution of the present example, even if relatively high voltage due to static electricity and the like is applied to the two pins P1 and P2 installed in the semiconductor device 150, a gate oxide film of the transistor can be prevented from being broken. On the other hand, in the conventional oscillation circuit 900 shown in FIG. 1, when relatively high voltage is applied to the first pin P1, the gate oxide film of the transistor included in the NAND circuit of the inverting amplifier 960 is relatively easy to be broken. Further, when relatively high voltage is applied to the second pin P2, the gate oxide film of the transistor included in the inverter of the buffer 970 is relatively easy to be broken. However, in the oscillation circuit 100E of the present example, the first transmission gate 210 (FIG. 3) is installed between the first pin P1 of the semiconductor device 150 and the input terminal of the first inverter 220 included in the inverting amplifier 160, and the second transmission gate 170 is installed between the second pin P2 of the semiconductor device 150 and the input terminal of the inverter 181 included in the buffer 180. Each transmission gate 210 and 170 has the “on” resistance of relatively high value. Therefore, when relatively high voltage due to static electricity and the like is applied to the first pin P1 of the semiconductor device 150, the first transmission gate 210 prevents the gate oxide film of the first inverter 220 from being broken. In addition, when relative high voltage is applied to the second pin P2 of the semiconductor device 150, the second transmission gate 170 prevents the gate oxide film of the inverter 181 from being broken.

In FIG. 11, though the transmission gate 170 is installed between the inverting amplifier 160 and the buffer 180, the transmission gate can be replaced by, for example, a resistor such as diffused resistor (referred to as diffused layered resistor, too). Here, the diffused resistor is a resistor device utilizing layer resistance of a diffused layer formed on a semiconductor substrate. However, relatively large area is needed in order to form the diffused layer having relatively large resistance value. Further, when the transmission gate 170 is replaced by the diffused resistor in a gate array, a forming position of the diffused resistor and a location of an oscillation circuit are limited. On the other hand, when the “on” resistance of the transmission gate 170 is utilized as the present example, there are advantages that relatively large resistance value can be obtained in even relatively small area, enhancing versatility in arranging an oscillation circuit in a gate array.

Here, it should be understood that the present invention is not limited to the above examples and embodiments and can be implemented with a variety of modifications within the spirit and scope of the present invention so as to apply the following modifications, for example.

(1) Though the crystal oscillator 110 is used alone in the above examples, a load capacitor may be connected to the crystal oscillator 110. In addition, though the oscillation circuit 100 can have the crystal oscillator 110, for example, a ceramic oscillator, such as PZT and PbTiO3 may be included instead of this. Generally, the oscillation circuit has only to have the oscillator.

(2) Though the feedback resistor 120 is installed outside the semiconductor device 150 in the above examples, the feedback resistor may be installed inside the semiconductor device. Further, the feedback resistor 120 can be omitted. However, if the feedback resistor is utilized as the above examples, the oscillator can be certainly oscillated.

(3) Though the inverter included in the inverting amplifier 160 is the CMOS inverter having the pMOS transistor and the nMOS transistor in the above example, the inverter, of which the pMOS transistor is replaced by the resistor, such as the diffused resistor, may be used instead of this.

Further, though the semiconductor device 150 includes the MOS transistor, of which the gate insulating film includes an oxide film, a MIS transistor, of which the gate insulating film includes other insulating film such as a nitride film, may be included instead of this. In addition, the gate of the transistor may be composed of poly silicon.

Further, though a gate array is used as the semiconductor device 150 in the above example, other integrated circuit may be used.

Generally, an inverting amplifier included in a semiconductor device has only to be formed by using insulated gate transistors.

While this invention has been described in conjunction with specific embodiments thereof, it is evident that many alternatives, modifications, and variations will be apparent to those skilled in the art. Accordingly, preferred embodiments of the invention as set forth herein are intended to be illustrative, not limiting. Various changes may be made without departing from the spirit and scope of the invention.

What is claimed is:

1. A semiconductor device utilizing an oscillator installed outside and having an inverting amplifier, which is installed in parallel with the oscillator, that intermittently outputs an oscillation signal in response to a given control signal, the inverting amplifier comprising:
a first terminal that receives a first signal from the oscillator;
a second terminal that provides a second signal to the oscillator;
a transmission gate installed between the first terminal and the second terminal, that is formed by using insulated gate transistors, set to an ‘on’ state where the first signal is transmitted in a case of the control signal being set to a first logical level, and set to an ‘off’ state where the first signal is not transmitted in the other case of the control signal being set to a second logical level;
an inverter installed between an output terminal of the transmission gate and the second terminal, formed by using the insulated gate transistors, and inverting a logical level of a given signal so as to output the second signal; and
a clamping circuit installed between the output terminal of the transmission gate and an input terminal of the inverter that is formed by using the insulated gate transistor, set to make the first signal output from the transmission gate applied to the input terminal of the inverter in a case of the control signal being set to the first logical level, and set to make predetermined voltage applied to the input terminal of the inverter in the other case of the control signal being set to the second logical level.

2. The semiconductor device claimed in claim 1, the transmission gate being a CMOS transmission gate, a combination of n-channel type MOS transistors and p-channel type MOS transistors.

3. The semiconductor device claimed in claim 1, further comprising:
a buffer, that is formed by using the insulated gate transistors, and that the signal output from the inverting amplifier to other circuits.

4. The semiconductor device claimed in claim 3, further comprising:
a transmission gate that is installed between the inverting amplifier and the buffer, and that is formed by using the insulated gate transistors.

5. The semiconductor device utilizing an oscillator claimed in claim 1, further comprising:
a feedback resistor that is installed in parallel with the oscillator.

6. An oscillation circuit, comprising:
an oscillator; and
a semiconductor device utilizing the oscillator,
the semiconductor device, comprising:
an inverting amplifier, that is installed in parallel with the oscillator, and that intermittently outputs an oscillation signal in response to a given control signal; and
the inverting amplifier, comprising:
a first terminal that receives a first signal from the oscillator;
a second terminal that provides a second signal to the oscillator;
a transmission gate installed between the first terminal and the second terminal, formed by using insulated gate transistors, set to an ‘on’ state where the first signal is transmitted in a case of the control signal being set to a first logical level, and set to an ‘off’ state where the first signal is not transmitted in the other case of the control signal being set to a second logical level;
an inverter installed between an output terminal of the transmission gate and the second terminal, that is formed by using the insulated gate transistors, and that inverts a logical level of a given signal so as to output the second signal; and
a clamping circuit installed between the output terminal of the transmission gate and an input terminal of the inverter, that is formed by using the insulated gate transistor, that is set to make the first signal output from the transmission gate applied to the input terminal of the inverter in a case of the control signal being set to the first logical level, and that is set to make predetermined voltage applied to the input terminal of the inverter in the other case of the control signal being set to the second logical level.
